(19) United States
(12) Patent Application Publication
(10) Pub. No.: US 2013/0112247 A1
(43) Pub. Date: May 9, 2013

(54) FRAME FOR SOLAR PANELS

(71) Applicants: Szu-Han Li, Zhongli City (TW); Thomas Tong Hong Fu, Taichung (TW)

(72) Inventors: Szu-Han Li, Zhongli City (TW); Thomas Tong Hong Fu, Taichung (TW)

(73) Assignee: Taiwan Semiconductor Manufacturing Co. Solar, Ltd., Taichung City (TW)

(21) Appl. No.: 13/292,200

(22) Filed: Nov. 9, 2011

(51) Int. Cl. H01L 31/048; B23P 11/00; H01L 23/32; H01L 31/18

(52) U.S. Cl. 136/251; 29/890.033; 29/428; 211/41.1

(57) ABSTRACT

A frame member is disclosed for a mounting a solar panel in a solar module. Embodiments of the frame member include an elongated outer sleeve having a channel configured for receiving an elongated inner reinforcing member disposed therein. The reinforcing member may be slidably inserted into the channel in some embodiments and is operable to structurally strengthen the outer sleeve. The reinforcing member may be made of a material having a greater tensile strength than the outer sleeve. A method for assembling the frame is also provided.

### FIELD

The present disclosure generally relates to photovoltaic solar cells, and more particularly to structural frames for supporting solar panels and methods for assembling the same.

### BACKGROUND

Solar cells represent one class of devices which harness a renewable source of energy in the form of light that is converted into useful electrical energy which may be used for numerous applications. Thin film solar cells are one type of solar cell comprised of multi-layered semiconductor structures formed by depositing various thin layers and films of semiconductor and other materials on a substrate that are operable to capture and convert light energy into electricity. Multiple solar cells are positioned between transparent/translucent top cover and bottom backing sheets of material to form flat panels commonly rectangular in configuration. These solar panels are environmentally sealed and the generally transparent top cover sheet is conventionally glass, which may be tempered in some embodiments to resist breakage. Some typical commercially available solar panels may have representative dimensions, for example without limitation, up to about 72 inches (1828.8 mm) in length and up to about 40 inches (1016 mm) in width. The thickness of the solar panel sheet may be on the order of less than ½ inch (12.7 mm), often approximately in the ballpark of about ¼ inch (6.35 mm).

Solar panels are typically mounted in a relatively rigid perimeter frame that supports the panel along the edges. Additional lateral or cross support members spanning between the perimeter frame are sometimes provided for extra support. The solar panel and frame assembly collectively define a solar cell module, which may be mounted in a rack system that may combine a plurality of modules into an array. The racks can be mounted on any suitable support or structure including without limitation for example poles or the walls or roofs of a building.

Solar cell frames experience static and dynamic loads created by the wind, snow, dead weight of the solar panel, and thermal expansion all of which cause deflection and twisting of the frames. The solar cell frames ideally should possess sufficient structural strength to adequately support the solar panel in a manner which minimizes forces and bending stresses in the panel, and particularly in the top cover sheet glass to prevent damage to the solar panel and cells therein. Conversely, it is also generally desirable that the frame be as light-weight as possible to minimize the total dead weight of the solar cell module and the static loads imparted thereby to a building or other support structure on which the modules are to be mounted. Heretofore, solar cell frames have commonly been made of anodized aluminum due to the light weight of the material. Aluminum, however, may not always provide the desired structural strength and rigidity to properly support the solar panel and minimize bending stresses particularly in the top glass cover sheet.

An improved solar cell frame is therefore desired in view of the foregoing design considerations.

### BRIEF DESCRIPTION OF THE DRAWINGS

The features of the embodiments will be described with reference to the following drawings where like elements are labeled similarly, and in which:

FIG. 1 is an exploded perspective view of a solar module according to one exemplary embodiment of the present disclosure including a solar panel and frame members;

FIG. 2 is a transverse cross-sectional view of an outer sleeve of the frame member of FIG. 1;

FIG. 3 is a transverse cross-sectional view of an inner reinforcing member of the frame member of FIG. 1;

FIG. 4 is a transverse cross-sectional view taken along line 4-4 in FIG. 1 showing the inner reinforcing member of FIG. 3 inserted in the outer sleeve of FIG. 2;

FIG. 5 is a perspective view of a frame member of FIG. 1 showing two inner reinforcing members of FIG. 3 partially inserted into the outer sleeve of FIG. 2;

FIG. 6 is a perspective view of a frame member of FIG. 1 showing the two inner reinforcing members of FIG. 3 fully inserted and locked into the outer sleeve of FIG. 2;

FIG. 7 is a perspective view of a locking system for securing the inner reinforcing member of FIG. 3 in the outer sleeve of FIG. 2, showing an end view of the frame member with the reinforcing member partially inserted in the outer sleeve;

FIG. 8 is a perspective view of the locking system of FIG. 7 showing an end view of the frame member with the reinforcing member fully inserted and locked into position in the outer sleeve;

FIG. 9 is a close up detail of a locking protrusion on the reinforcing member of the locking system of FIGS. 7 and 8;

FIG. 10 shows various alternative embodiments of possible cross-sectional shapes of the reinforcing member of FIG. 3; and

FIG. 11 is a computer-generated image showing the results of a computer stress analysis modeling of the frame member of FIG. 1.

All drawings are schematic and are not drawn to scale.

### DETAILED DESCRIPTION

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation.

Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

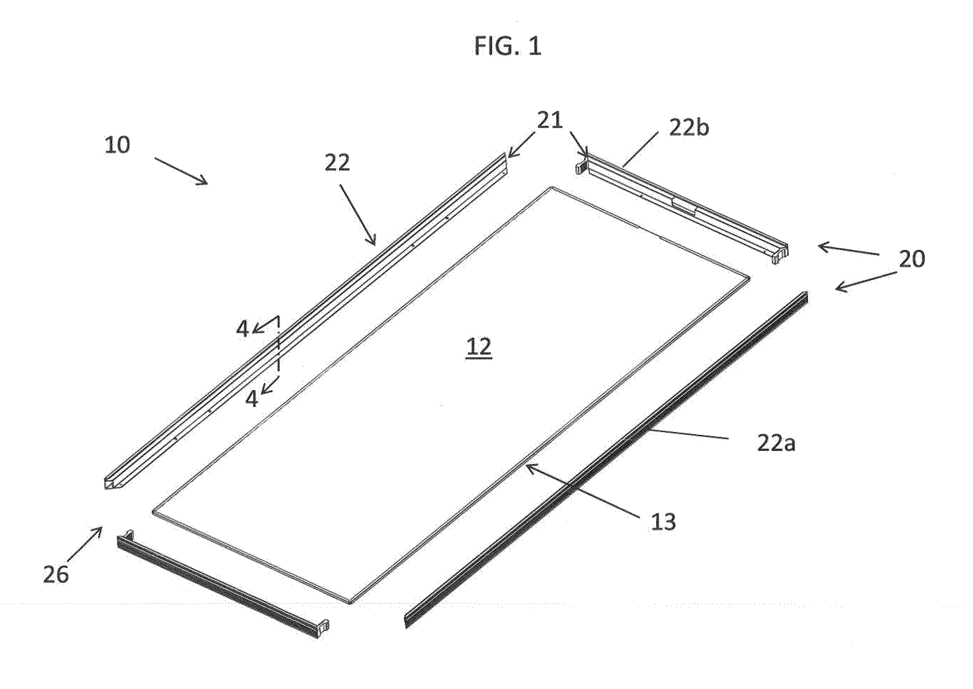

FIG. 1 shows a first embodiment of a solar cell module 10 according to the present disclosure having a compound frame 20 that combines at least two separate structural members each made of a different material having differing mechanical properties including density, tensile strength, and modulus of elasticity. In one embodiment, as further described herein, the structural members may be assembled together without the use of mechanical fasteners such as screws, rivets, welding, adhesives, or other similar conventional methods.

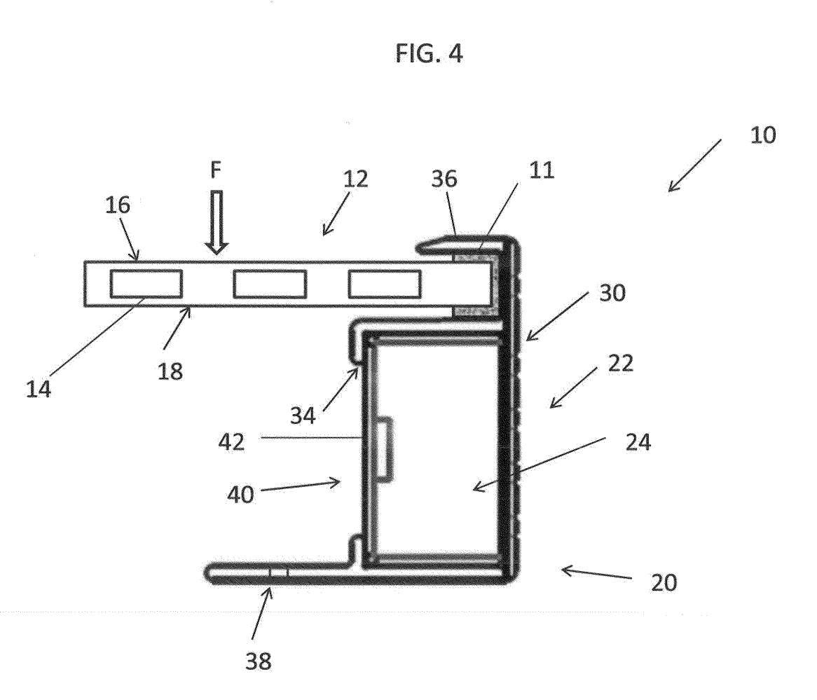

Referring to FIG. 1, solar cell module 10 includes a conventional solar panel 12 mounted in and supported by frame 20. Solar panel 12 includes a plurality of solar cells 14 (see also FIG. 4) of any suitable number arranged in any suitable pattern and orientation within the panel. In some embodiments, solar cells 12 may be any commercially-available photovoltaic energy conversion device capable of converting any type or wavelength of light energy or radiation into electrical energy. Accordingly, solar cells 14 useable in solar panel 12 may include for example, without limitation , thin film solar cells including those having absorbing layers made from crystalline and/or amorphous silicon, cadmium telluride (CdTe), and copper indium gallium diselenide (CIGS), dye-sensitized solar cells, and others. It will be appreciated; therefore, that solar panel 12 may be any type of solar energy conversion panel having a sheet-like configuration that can be suitably mounted and supported in frame 20.

FIG. 4 shows solar panel 12 mounted in solar frame 20. Referring to FIGS. 1 and 4, solar panel 12 generally includes a light-transmitting top cover sheet 16 that is positioned to receive incident light energy or radiation, bottom backing sheet 18, and solar cells 14 disposed and encapsulated or laminated therebetween by a suitable adhesive or epoxies conventionally used in the art. Suitable backing sheets 18 may include glass, polymers, metals, and various composites formed of two or more materials including glass or carbon fiber reinforced polymers or fiberglass.

Top cover sheet 16 is transparent and may be made of materials including glass and polymers capable of transmitting light to solar cells 14 positioned below sheet 16. In some embodiments, top cover sheet 16 is transparent glass, which may or may not be tempered to better withstand static, bending, and impact loads such as those caused by hail without breakage or cracking Top cover sheet 16 is therefore subjected to and should be made of a suitable transparent material and thickness to resist deflection and impacts without substantial damage.

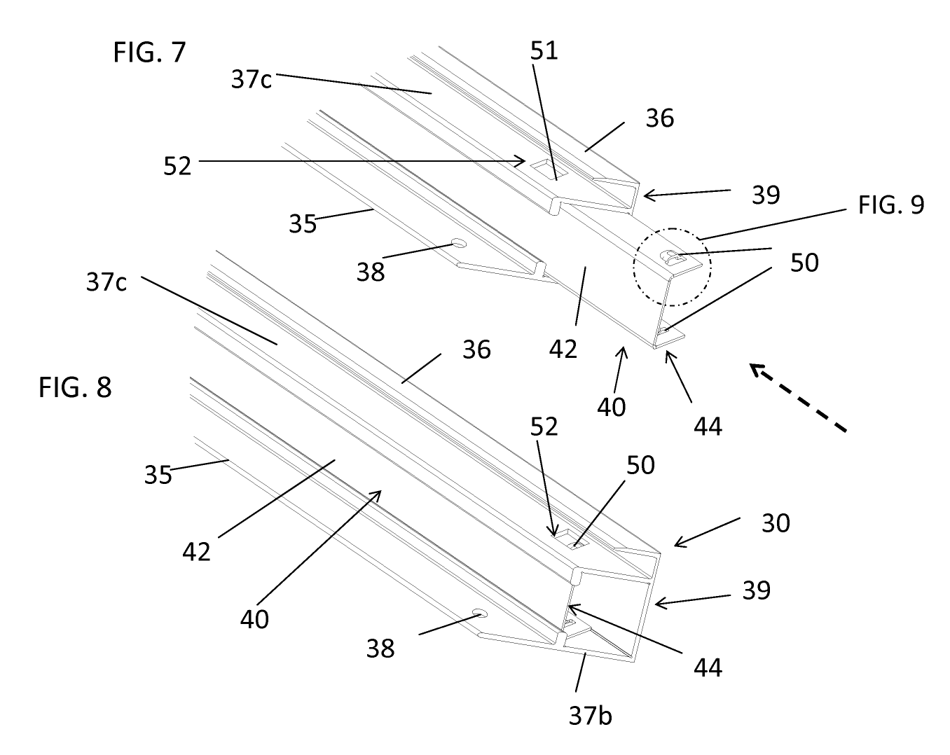

Referring now to FIGS. 1-4, solar frame 20 is configured as a perimeter frame for supporting the edge portions 13 of solar panel 12. In one embodiment, frame 20 may include four axially elongated frame members 22 including two longitudinal frame members 22a and two lateral frame members 22b that are joined together at their ends 21 to form corners 26. Frame members 22 define a longitudinal axis LA, and may be oriented perpendicular to each other and joined to form a rectilinear shaped perimeter frame. In one embodiment, frame members 22a have a longer length than members 22b to form a generally rectangular frame as shown in FIG. 1. Frame members 22a, 22b may be joined by any suitable mechanical means commonly used in the art including without limitation fasteners (e.g. screws, bolts, rivets, etc.) welding, adhesives, clips, etc. In some embodiments, ends 21 may be beveled or angled in configuration (best shown in FIGS. 7 and 8) to form a miter joint corner 26. In other embodiments, corners 26 may be a butt joint with straight ends 21 of each frame member 22 being squarely abutted and joined.

According to some embodiments, as shown in FIGS. 1-6, frame members 22 may have a generally open tubular configuration that defines an open central void 24. Frame members 22 may have any suitable cross-sectional shapes or combinations of shapes including without limitation rectilinear shapes such as rectangular, square, trapezoidal, triangular, etc. In one possible embodiment, frame members 22 may have a generally rectangular cross-sectional shape as shown in FIG. 4.

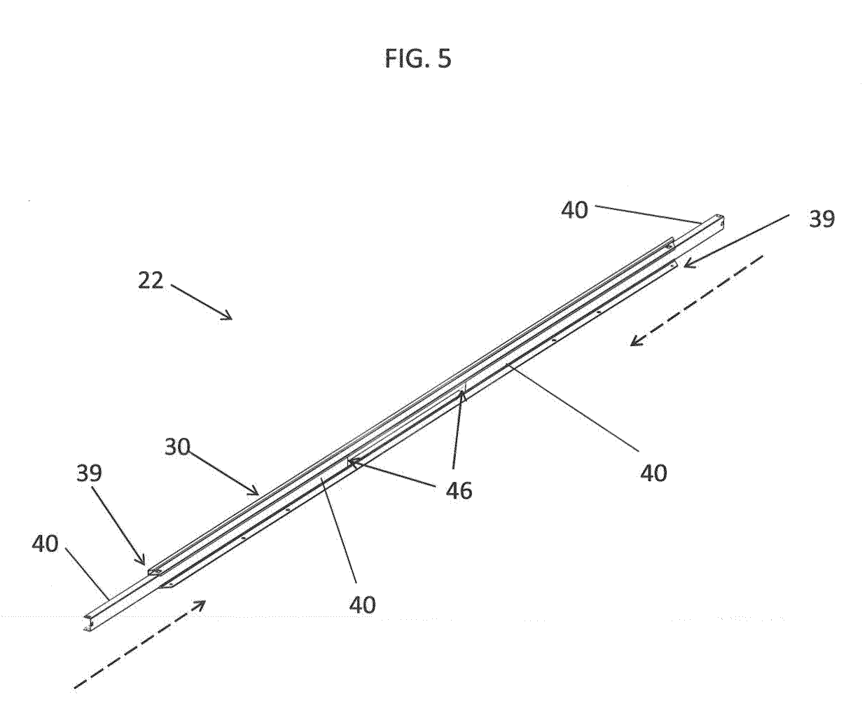

Referring to FIGS. 1-6, solar frame 20 may be a compound frame with at least one, but at least two of frame members 22 including an axially elongated outer sleeve 30 and axially elongated inner reinforcing insert or member 40 for adding structural strength to the sleeve. In one embodiment, reinforcing member 40 is slidably axially insertable into outer sleeve 30 (see, e.g. FIG. 5 and directional insertion arrows). Outer sleeve 30 has an axial length that is at least twice the lateral width of the sleeve measured transverse to longitudinal axis LA.

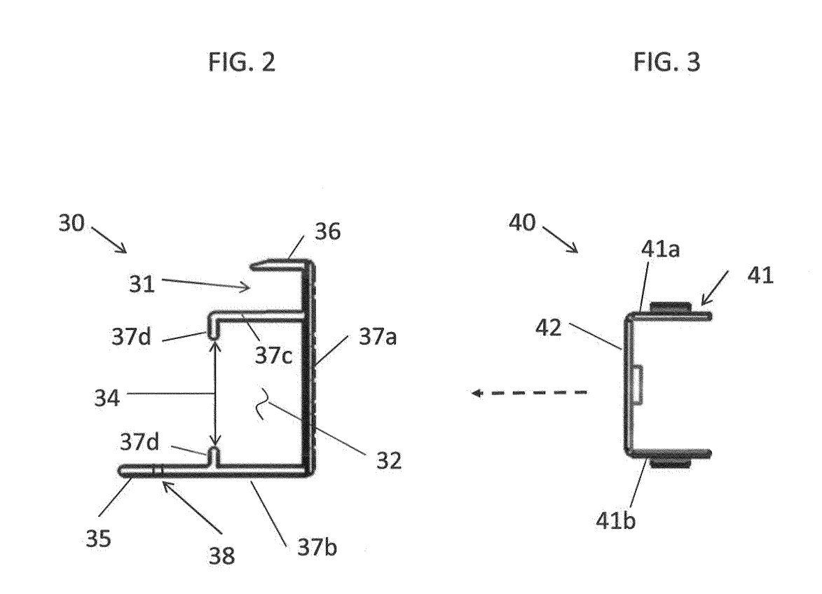

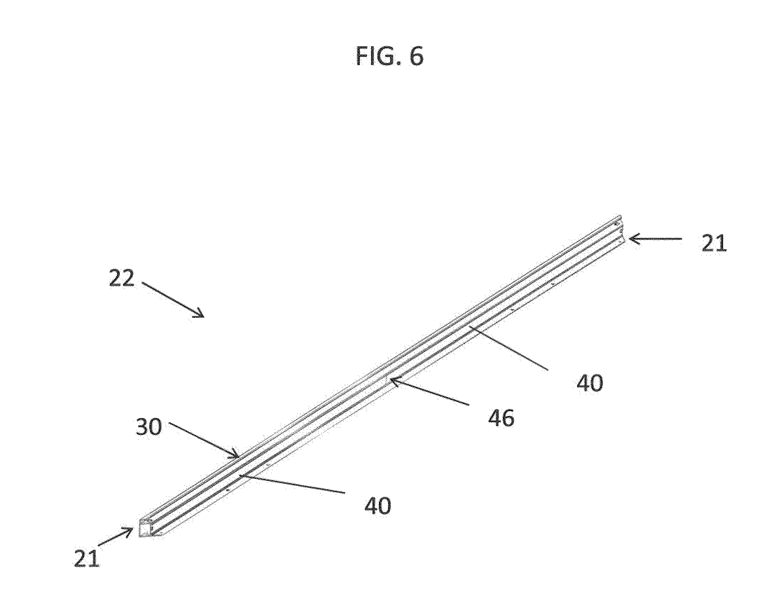

Outer sleeve 30 may generally approximate a tubular shape and is at least partially hollow or open in structure when viewed in cross-section (see, e.g. FIG. 2) in some embodiments to form a partially enclosed interior chamber or channel. In one embodiment, outer sleeve 30 therefore defines at least one axially extending and elongated open channel 32 that is configured and dimensioned to receive member 40 at least partially therein. In some embodiments, channel 32 may extend for part of or substantially the entire length of outer sleeve 30 (see, e.g. FIGS. 5 and 6) so that one or more reinforcing members 40 may be inserted to cover substantially the entire length of the sleeve for strengthening.

Outer sleeve 30 and reinforcing member 40 are complementary-configured as shown in FIGS. 2-4 so that the member 40 is positioned in close proximity to and/or at least partially engages the sleeve when positioned therein to provide added structural reinforcement against bending and deflection when laterally or transversely oriented loads F are applied to solar panel 12 which is supported by frame 20. Outer sleeve 30, with added support from reinforcing member 40, advantageously better resists bending thereby minimizing deflection and stress in cover glass 16, which might otherwise crack or damage the cover glass if the concomitant deflection of frame members 22 becomes too great under load. The reinforcing members 40 therefore add strength to the overall solar module 10.

Referring to FIG. 2, outer sleeve 30 generally includes a vertical side wall 37a, horizontal base wall 37b, and top wall 37c. Side wall 37a and base wall 37b may be oriented perpendicular to each other. Top wall 37c is arranged parallel to and spaced apart from horizontal base wall 37b in opposing relationship in some embodiments. Walls 37a, 37b, and 37c generally define channel 32. In some embodiments, base wall 37b may have a greater width than top wall 37c (when viewed in FIG. 2) to define a mounting flange 35 that protrudes laterally beyond channel 32 for securing the frame 20 to a rack system or directly onto a support structure (e.g. wall, roof, or other structure) for mounting solar panels 12. In some embodiments, mounting flange 35 may include one or more mounting holes 38 (see also FIGS. 7 and 8) for inserting fasteners such as screws or bolts therethrough to mount the frame 20 to the support structure or rack system.

Outer sleeve 30 may further include a pair of opposing and spaced apart stub walls 37d as shown in FIG. 2. Stub walls 37d are vertically shorter in height than side wall 37a and define an inwards facing open window 34 (inwards being defined as being towards the interior of solar module 10 when the frame is fully assembled) that extends axially along the length of the outer sleeve 30. In some embodiments, window 34 extends for substantially the entire length of outer sleeve 30. Window 34 is disposed opposite and oriented parallel to side wall 37a thereby making channel 32 laterally open to reduce weight which is made possible by reinforcing member 40 which braces outer sleeve 30. The stub walls 37d also serve to laterally retain the reinforcing member 40 in channel 32, in which case the member may be inserted into the channel through the open ends of the channel and outer sleeve 32 in this embodiment. The laterally open channel window 34 also adds vertical flexibility to allow the top wall 37c to elastically deflect slightly upwards when reinforcing member 40 is inserted therein to facilitate the locking protrusion 50 joining mechanism further describe herein.

In other possible embodiments, channel 32 may be fully enclosed. Window 34 may be continuous and extend for the entire length of outer sleeve 30 as shown in FIGS. 5-6, or in some other embodiments contemplated may be comprised of a series of longitudinally spaced apart and intermittent windows that open laterally into channel 32 (not shown).

Referring to FIGS. 2 and 4, outer sleeve 30 may include a generally horizontal panel flange 36 depending from and oriented perpendicular to vertical side wall 37a. Panel flange 36 defines an inwards facing gap 31 between the flange and top wall 37c which is configured and dimensioned to receive and support at least the edge portion 13 of solar panel 12 therein (see FIG. 4). In some possible embodiments, solar panel 12 may be mounted in gap 31 with any commercially available and suitable adhesive sealant or glue 11 commonly used in the art for mounting solar panels, such as without limitation silicone, urethane, or butyl based polymer adhesive sealants. The sealant or glue helps to affix and cushion the panels in the frame 20.

Outer sleeve 30 is made of a material that is lighter in weight and therefore may be less dense than reinforcing member 40. Accordingly, in some possible embodiments, sleeve 30 may be made from materials such as aluminum or aluminum alloys. In one embodiment, as an example without limitation, sleeve 30 may be made from type/grade 6063 T5 aluminum alloy having a density of 2.7 g/cc, tensile strength of 145 MPa, and modulus of elasticity of 68.9 GPa. Outer sleeve 30 preferably is made of a corrosion resistant material since solar modules 10 are exposed to the weather. In other possible embodiments, outer sleeve 30 may be made of magnesium aluminum alloy, titanium, or stainless steel.

Referring now to FIG. 3, reinforcing member 40 in some embodiments includes a pair of axially extending and spaced apart horizontal flange walls 41 and at least one axially extending vertical web 42 connecting the flange walls together. In one embodiment, the flange walls include an upper flange wall 41a and lower flange wall 41b. The flange walls 41 have a lateral or horizontal width and web 42 has a vertical height that are cooperatively selected to complement the corresponding dimensions and shape of channel 32 in outer sleeve 30 (see FIGS. 2 and 4) so that the member 40 is insertable into the channel.

In one embodiment, reinforcing member 40 has a cross-sectional shape that mates with and is complementary configured to the cross-section shape of channel 32 in outer sleeve 30 so that the member may be slidably inserted into and received by the channel.

Reinforcing member 40 defines load bearing surfaces that are engageable with corresponding load bearing surfaces disposed on the outer sleeve 30 adjacent channel 32. Reinforcing member 40 includes at least two contact load bearing surfaces, which in one embodiment shown in FIG. 4 may be defined on upper flange wall 41a and lower flange wall 41b. These load bearing surfaces are configured and arranged to engage corresponding load bearing surfaces disposed on outer sleeve 30 adjacent channel 32. Reinforcing member 40 has overall outer dimensions in cross section (i.e. a height and width measured transverse to longitudinal axis LA) that are just slightly smaller than corresponding interior surfaces of outer sleeve 32 adjacent the channel (see, e.g. FIG. 4). Accordingly, portions of reinforcing member 40 are closely spaced near or partially engaging the outer sleeve adjacent channel 32 when the member is positioned in the channel. This locates at least the upper and/or lower flange walls 41a, 41b with load bearing surfaces defined thereon in close proximity to or slightly engaging the corresponding sleeve load bearing surfaces defined on base wall 37b and top wall 37c adjacent channel 32, as shown in FIGS. 4 and 8. In this manner, vertical loads imposed onto the top or bottom of outer sleeve 30 may be transmitted to the flange walls 41a, 41b and through the vertical web 42 before substantial deflection of the outer sleeve, thereby reinforcing the channel portion and overall outer sleeve to better resist deflection/bending and twisting particularly at mid-span of the frame members 22.

In one possible embodiment, as shown in FIGS. 3 and 4, reinforcing member 40 may have a generally C-shaped cross-sectional structural shape (viewed transverse to longitudinal axis LA) with a single vertical web 42 and flange walls 41 that are arranged parallel to each other. Web 42 is horizontally offset from the vertical centerline of the C-shaped section. In this embodiment, channel 32 of outer sleeve 30 may have a generally rectangular or square cross-sectional shape that complements the C-shape of reinforcing member 40 (see, e.g. FIG. 4).

Reinforcing member 40 may have any other suitable cross-sectional shape so long as the shape generally conforms to the cross-sectional shape of the open channel 32 or other passageway provided in outer sleeve 30 to slidably receive reinforcing member 40 and is operable to reinforce the channel and outer sleeve. FIG. 10 shows some examples of some other possible closed tubular shapes for reinforcing member 40 other than the open C-shaped section shown in FIG. 3, including triangular, trapezoidal, triangular with chamfered corners, an I-beam shape (top row, left to right), square, rectangular with an chamfered corner, rectangular section with curved or convex side, and rectangular (bottom row, left to right). Numerous other variations are possible including various rectilinear, polygonal, circular, elliptical/oval cross-sectional shapes including those truncated sides or corners, or other unique configurations to fit the cross-sectional shape of the channel 32 or other passageway provided. Accordingly, the embodiments are not limited to those expressly disclosed herein.

Reinforcing member 40 is made of a material that has greater tensile strength than outer sleeve 30. In some embodiments, reinforcing member 40 may be heavier in weight and therefore denser than sleeve 30. Accordingly, in some possible embodiments, sleeve 30 may be made from materials such as steel or steel alloys including stainless steel for corrosion resistance. In one embodiment, as an example without limitation, sleeve 30 may be made from type/grade SUS 304 stainless steel having a density of 7.8 g/cc, tensile strength of 250 MPa, and modulus of elasticity of 210 GPa. In other possible embodiments, reinforcing member 40 may be made of titanium, magnesium aluminum alloy, or other suitable materials that have a greater tensile strength and density than the material from which outer sleeve 30 is made

Outer sleeve 30 and reinforcing member 40 may be fabricated by any conventional methods used in the art for forming frame members and components. Suitable fabrication methods include alone or in combination, without limitation, extrusion, milling, machining, stamping, forging, molding, casting, and others. It is well within the ambit for one skilled in the art to select an appropriate fabrication method based on the shape to be made and the material used for sleeve 30 or member 40.

The reinforcing members 40 have an axial length substantially greater than the transverse width of the member and also outer sleeve 30, as they are intended to longitudinally reinforce the sleeve for a majority of its length in some embodiments. As shown in FIGS. 5 and 6, two or more reinforcing members 40 may be used and mounted in a single outer sleeve 30. This makes it easier to handle the members 40 and assemble them into the outer sleeve 30, as well as providing a means for securing the members to the sleeve near each end of the sleeve as further described herein and shown additionally in FIGS. 7-9. Where multiple members 40 are used, each member may have an axial length shorter than the axial length of outer sleeve 30. The ends of adjoining members may be abutting or at least proximate to each other within channel 32 as shown in FIG. 6 to form a substantially continuous reinforcement of the outer sleeve along its length. In some embodiments, the reinforcing members 40 have a length that may be at least about one half the length of the outer sleeve 30 as shown in FIGS. 5 and 6. When two or more members 40 are used, the members may have a combined total length that is substantially coextensive with the length of outer sleeve 30 in some embodiments as shown in FIGS. 5 and 6 so that substantially the entire length of the sleeve is reinforced and strengthened.

In other embodiments, a single reinforcing member 40 may be used having an axial length that is substantially coextensive with the length of channel 32 and outer sleeve 30 (except possibly for the angle-cut mitered ends of the sleeve).

One or more reinforcing members 40 may be mounted and attached to outer sleeve 30 by any suitable method. In some embodiments, members 40 may be removably secured to outer sleeve 30 via any suitable mechanical fastening technique used in the art.

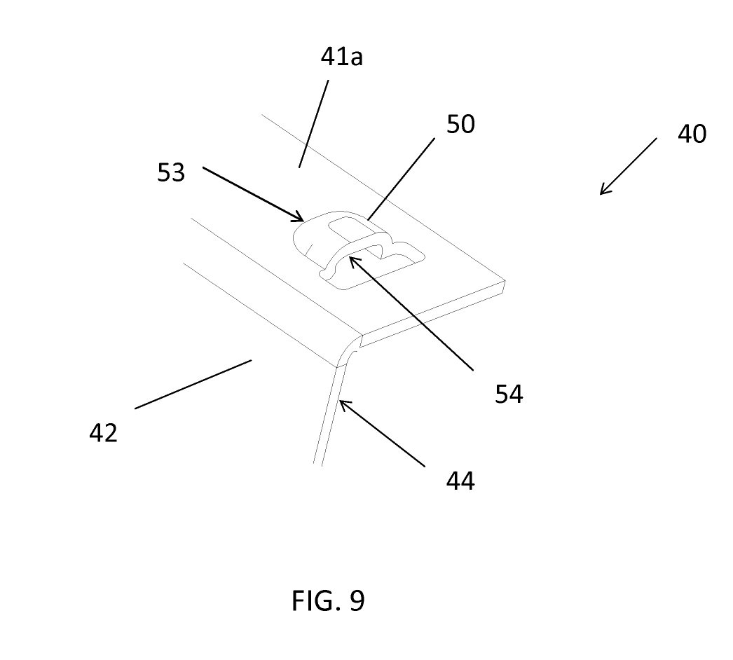

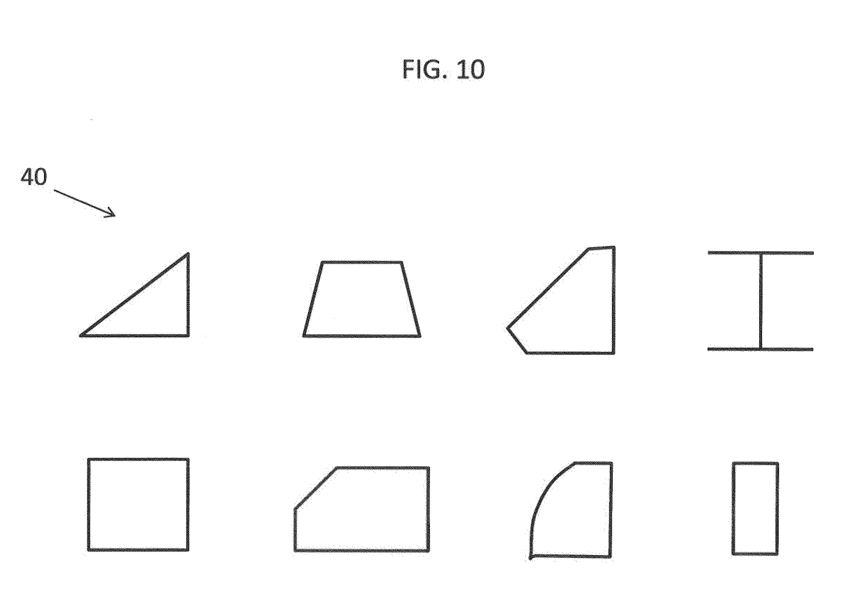

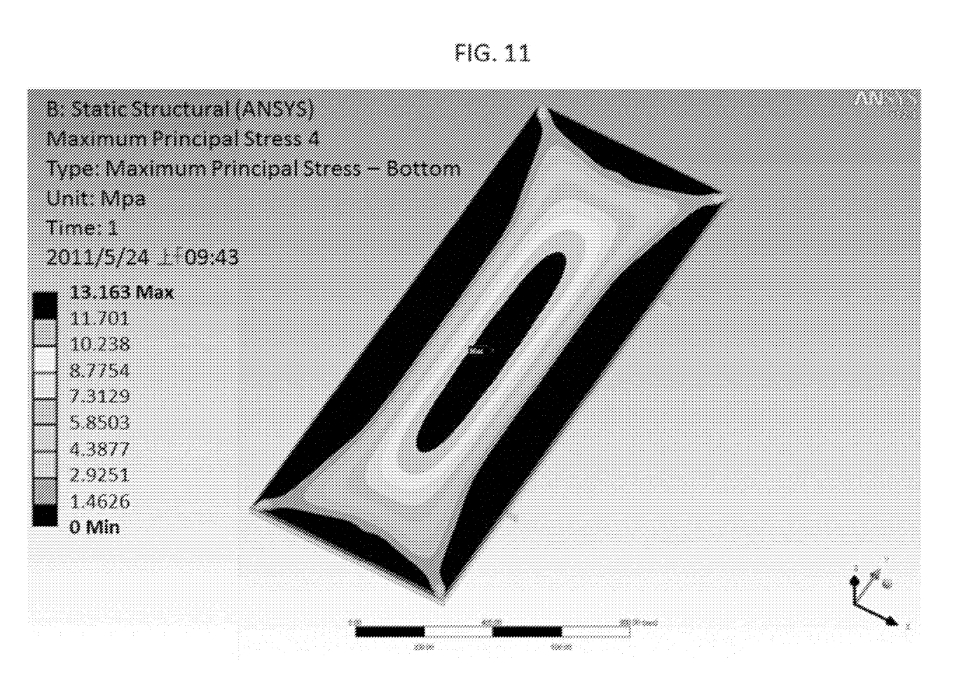

Referring to FIGS. 7-9, members 40 may advantageously be secured to outer sleeve 30 without the use of separate fasteners (e.g. screws) or welding, brazing, or soldering . Members 40 may include one or more raised locking protrusions 50 that are configured and dimensioned to be received in complementary configured locking apertures 52 disposed in outer sleeve 30. In one embodiment, as shown, two locking protrusions 50 and corresponding locking apertures 52 may be provided which are each disposed proximate to one end of the member 40 and sleeve 30, respectively. The remaining opposing ends of member 40 and sleeve 30 may be plain. In this embodiment, one locking protrusion 50 is disposed on each flange wall 41 of reinforcing member 40. A corresponding locking aperture 52 is disposed in the base wall 37b and opposing top wall 37c. Locking protrusions 50 may be configured to include a slightly rounded portion 53 (see FIG. 9) and an opposite transversely oriented flat bearing surface 54 that is configured to engage a similarly oriented flat bearing surface 51 defined in outer sleeve 30 by locking aperture 52.

In some embodiments, the reinforcing members 40 may be removably inserted in outer sleeve 30 such that the locking protrusions 50 may each be pressed inwards with sufficient force to disengage the protrusions from the locking apertures 52, thereby allowing the member to be slid out of the outer sleeve.

It will be appreciated that in some embodiments, the locking protrusions 50 may alternatively be provided on the outer sleeve 30 and the locking apertures 52 may be provided on the reinforcing member 40.

An exemplary method of mounting reinforcing member 40 in outer sleeve 30 will now be described, with general reference to FIGS. 5-9. For this example, it is assumed that two locking protrusions 50 and mating apertures 52 are provided as shown. Other suitable number and/or locations of locking protrusions and apertures may be provided in other embodiments.

To assemble frame member 22 and mount reinforcing member 40 into outer sleeve 30, the plain end 46 of a first member 40 opposite locking tabs 50 is first slidably inserted through an open end 39 of outer sleeve 30 into channel 32, as shown in FIGS. 5 and 7. As the member 40 is slid into outer sleeve 30, the rounded portion 53 of locking protrusions 50 proximate to locking end 44 will eventually engage the edge of the end of outer sleeve 30 having the locking apertures 52. Due to the close proximity of the flange walls 41a, 41b on member 40 to base wall 37b and top wall 37c on sleeve 30 (see, e.g. FIGS. 4 and 7-8), the member 40 and/or the outer sleeve 30 will slightly flex and elastically deflect inwards or outwards, respectively, in the vicinity of the locking protrusion 50. Window 34 opening into channel 32 also facilitates the elastic deflection of outer sleeve 30 in response to contact by the locking protrusion 50.

Reinforcing member 40 continues sliding inside channel 32 of outer sleeve 30 with locking protrusions 50 sliding above base wall 37b and beneath top wall 37c respectively until the protrusions encounter locking apertures 52 in the outer sleeve. At this point, the locking position is reached, as shown in FIGS. 6 and 8. The locking protrusions 50 will each at least partially emerge from their respective locking apertures 52 and project slightly outwards from the apertures, as best shown in FIG. 8. Bearing surfaces 54 on the locking protrusions 50 are now positioned and axially aligned in opposing relation to bearing surfaces 51 defined by apertures 52. If the installer attempts to axially withdraw the member 40 from outer sleeve 30, bearing surfaces 51 and 54 will become mutually engaged to prevent removal of the member from the sleeve. The member 40 is thereby secured and locked into outer sleeve 30 to prevent relative axial movement between the member and outer sleeve. As also shown in FIGS. 4 and 8, vertical web 42 of member 40 is visible through and is positioned adjacent window 34 of outer sleeve 30, which close offs the outer sleeve to prevent infiltration of debris or other substances into the frame 20. The web 42 further defines a fully enclosed tubular shape of the assembled frame member 22, when viewed in cross-section as shown in FIG. 4.

In the case where two reinforcing members 40 are used that take up substantially the entire length of outer sleeve 30, the second member 40 may be inserted through the remaining end 39 of the outer sleeve and locking into position in a similar manner to that just described. The completed compound frame member 22 would appear as shown in FIG. 6. At this point, the compound frame member 22 is ready for assembly to the solar panel 12 in solar module 10 as shown in FIG. 1.

Referring to FIG. 1, in some embodiments at least the two longitudinal frame members 22a having the greatest length and susceptible to the largest amount of deflection under lateral forces F (see FIG. 4) may be provided with reinforcing members 40. In other embodiments, the shorter lateral frame members 22b may also include members 40 so that the entire solar frame 20 is fully reinforced.

Advantageously, the foregoing embodiments of a structurally reinforced compound solar frame member 22 are operable to better resist deflection and twisting under static and dynamic loads. This minimizes the resulting stresses in the solar panel, and particularly the top glass cover sheet which is susceptible to cracking and damage. In addition, added advantages of embodiments of a compound solar frame member disclosed herein are that the size of the outer sleeve 30 need not be increased and the aesthetic appearance of the visible portions of frame member when the solar module is assembled is not changed. This is made possible by structurally reinforcing the outer sleeve 30 from inside via inner reinforcing member 40 as disclosed herein.

### EXAMPLE

### Computer Stress Analysis

The inventors performed a computer-simulated static structural stress analysis to compare an unreinforced solar panel frame with a reinforced frame 20 utilizing reinforcing members 40 and outer sleeve 30 according to embodiments of the present disclosure. The simulation was performed using ANSYS version 12.1 structural stress analysis software available from ANSYS, Inc. The virtual solar modules analyzed were configured similar to solar module 10 shown in FIG. 1. The modules included a glass top cover sheet 5.8 mm thick and perimeter frame measuring 1656 mm long by 650 mm wide by 35 mm high. The unreinforced frame analyzed was made of grade/type 6063 T5 aluminum. The reinforced frame was made of the same aluminum outer sleeve but with a grade/type SUS 304 steel reinforcing member.

The maximum principal stress on the glass cover sheet at the physical center of the solar panel was determined by the stress analysis. This is the area of the greatest deflection of the glass sheet and bending moment. The results indicated a reduction in the maximum principal stress from 14.275 MPa (unreinforced frame) to 13.163 MPa (reinforced frame). An exemplary computer-generated stress distribution in the solar panels showing results for the reinforced frame is shown the computer-generated image of FIG. 10.

According to one exemplary embodiment of the present disclosure, a frame for supporting a solar panel includes at least one elongated frame member defining a longitudinal axis and being configured for supporting a solar panel. The frame member includes an axially elongated outer sleeve defining a longitudinally-extending channel configured for receiving an axially elongated reinforcing member disposed therein. The reinforcing member is engageable with the outer sleeve and operable to structurally support the sleeve. The outer sleeve is made of a first material and the reinforcing member being made of a second material different than the first material; the second material having a greater tensile strength than the first material. In some embodiments, the second material has a greater density than the first material. In one representative embodiment, without limitation, the outer sleeve may be made of aluminum including alloys thereof and the inner sleeve may be made of steel or titanium including alloys thereof.

According to one exemplary embodiment of the present disclosure, a solar module includes a solar panel including a plurality of solar cells and a perimeter frame supporting the solar panel. The frame includes a plurality of elongated frame members each defining a longitudinal axis. At least one frame member includes an axially elongated outer sleeve having a first length and a longitudinally-extending channel formed therein, and one or more axially elongated reinforcing members having a second length and being elongated in a direction of the first length of the outer sleeve. The reinforcing member or members are received in the channel of the outer sleeve for structurally strengthening the sleeve. The outer sleeve is made of a first material and the reinforcing member is made of a second material different than the first material; the second material having a greater tensile strength than the first material for reinforcing the frame. In some embodiments, the one or more reinforcing members have a total combined length that is substantially coextensive with the first length of the outer sleeve. The channel may have a rectangular or square cross sectional shape in some embodiments and the reinforcing member or members may have a complementary shape that allows the member to be slid into the channel from an open end of the outer sleeve.

One exemplary embodiment of a method for assembling a compound solar frame member for a solar module includes: providing an elongated outer sleeve defining a longitudinal axis and a longitudinally-extending channel therein, the outer sleeve configured for holding a solar panel and being made of a first material; providing at least one axially elongated reinforcing member, the reinforcing member being made of a second material different than the first material, the second material have a greater tensile strength than the first material; inserting one end of the reinforcing member through an open end of the outer sleeve into the channel; sliding the reinforcing member axially inside the channel to a locking position; and securing the reinforcing member in the channel to the outer sleeve to prevent relative longitudinal movement between the member and sleeve.

While the foregoing description and drawings represent exemplary embodiments of the present invention, it will be understood that various additions, modifications and substitutions may be made therein without departing from the spirit and scope and range of equivalents of the accompanying claims. In particular, it will be clear to those skilled in the art that the present invention may be embodied in other forms, structures, arrangements, proportions, sizes, and with other elements, materials, and components, without departing from the spirit or essential characteristics thereof. One skilled in the art will further appreciate that the invention may be used with many modifications of structure, arrangement, proportions, sizes, materials, and components and otherwise, used in the practice of the invention, which are particularly adapted to specific environments and operative requirements without departing from the principles of the present invention. In addition, numerous variations in the exemplary methods and processes described herein may be made without departing from the spirit of the invention. The presently disclosed embodiments are therefore to be considered in all respects as illustrative and not restrictive, the scope of the invention being defined by the appended claims and equivalents thereof, and not limited to the foregoing description or embodiments. Rather, the appended claims should be construed broadly, to include other variants and embodiments of the invention, which may be made by those skilled in the art without departing from the scope and range of equivalents of the invention.

What is claimed is:

1. A frame for supporting a solar panel, the frame comprising:
at least one elongated frame member defining a longitudinal axis and configured for supporting a solar panel, the frame member including an elongated outer sleeve defining a longitudinally-extending channel configured for receiving an elongated inner reinforcing member being disposed therein, the reinforcing member having load bearing surfaces engageable with the outer sleeve and being operable to structurally support the sleeve;
the outer sleeve being made of a first material and the reinforcing member being made of a second material different than the first material, the second material have a greater tensile strength than the first material.

2. The frame of claim 1, wherein the second material has a greater density than the first material.

3. The frame of claim 1, wherein outer sleeve is made of aluminum including alloys thereof and the inner sleeve is made of steel or titanium including alloys of each thereof.

4. The frame of claim 1, wherein the outer sleeve defines a longitudinally-extending window opening laterally through the sleeve into the channel, the reinforcing member having a portion positioned adjacent to and closing the window.

5. The frame of claim 1, wherein the reinforcing member has a length substantially coextensive with the length of the channel of the outer sleeve.

6. The frame of claim 1, wherein channel and reinforcing member have transverse cross-sections that are complementary configured.

7. The frame of claim 6, wherein the load bearing surfaces of the reinforcing member are defined by an upper flange wall and a lower flange wall that are disposed proximate to surfaces of the outer sleeve surrounding the channel.

8. The frame of claim 1, wherein the outer sleeve includes a horizontal base wall, a top wall spaced apart from the base wall, and a vertical side wall joined to the base and top walls, the walls defining the channel in the outer sleeve.

9. The frame of claim 4, wherein the reinforcing member has a transverse cross-sectional shape that is complementary configured to a corresponding portion of the channel.

10. The frame of claim 4, wherein the reinforcing member has a C-section shape in cross section and the channel has a rectangular or square shape in cross section.

11. The frame of claim 5, wherein the reinforcing member includes at least one locking protrusion configured to engage a mating locking aperture formed in the outer sleeve, the locking protrusion being operable to prevent the reinforcing from being axially withdrawn from the outer sleeve.

12. A solar module comprising:
a solar panel including a plurality of solar cells;
a perimeter frame supporting the solar panel and including a plurality of elongated frame members each defining a longitudinal axis, at least one frame member including:
an axially elongated outer sleeve having a first length and a longitudinally-extending channel therein; and
one or more axially elongated reinforcing members having a second length and being elongated in a direction of the first length of the outer sleeve, the reinforcing member or members being received in the channel of the outer sleeve for structurally strengthening the sleeve;
the outer sleeve being made of a first material and the reinforcing member being made of a second material different than the first material, the second material have a greater tensile strength than the first material for reinforcing the frame.

13. The solar module of claim 12, wherein the one or more reinforcing members have a total combined length that is substantially coextensive with the first length of the outer sleeve.

14. The solar module of claim 12, wherein the channel has a rectangular or square cross sectional shape and the reinforcing member or members have a complementary shape that allows the member to be slid into the channel from an open end of the outer sleeve.

15. The solar module of claim 12, wherein the second material has a greater density than the first material.

16. The solar module of claim 12, wherein outer sleeve is made of aluminum and the inner sleeve is made of steel or titanium.

17. The solar module of claim 12, wherein the reinforcing member includes a locking protrusion or aperture that engages an other of a locking protrusion or aperture in the outer sleeve for securing the member to the sleeve.

18. A method for assembling a compound frame member for a solar module, the method comprising:
providing an elongated outer sleeve defining a longitudinal axis and a longitudinally-extending channel therein, the outer sleeve configured for holding a solar panel and being made of a first material;
providing at least one axially elongated reinforcing member, the reinforcing member being made of a second material different than the first material, the second material have a greater tensile strength than the first material;
inserting one end of the reinforcing member through an open end of the outer sleeve into the channel;
sliding the reinforcing member axially inside the channel to a locking position; and
securing the reinforcing member in the channel to the outer sleeve to prevent relative longitudinal movement between the member and sleeve.

19. The method of claim 18, wherein the securing step includes engaging one of a locking protrusion or aperture on the reinforcing member with an other one of a locking protrusion or aperture on the outer sleeve.

20. The method of claim 18, further comprising a step of closing a longitudinally-extending open window extending laterally into the channel with the reinforcing member.
